(19) United States
(12) Patent Application Publication
(10) Pub. No.: US 2025/0373224 A1
(43) Pub. Date: Dec. 4, 2025

(54) THIN-FILM SUSPENDED MICROACOUSTIC RESONATORS FOR TIMING APPLICATIONS

(71) Applicant: University of Central Florida Research Foundation, Inc., Orlando, FL (US)

(72) Inventors: Hakhamanesh MANSOORZARE, Orlando, FL (US); Reza ABDOLVAND, Winter Park, FL (US)

(21) Appl. No.: 19/220,998

(22) Filed: May 28, 2025

Related U.S. Application Data
(60) Provisional application No. 63/652,328, filed on May 28, 2024.
(60) Provisional application No. 63/656,867, filed on Jun. 6, 2024.

(51) Int. Cl. H03H 9/02; H03H 9/15; H03H 9/17

(52) U.S. Cl. CPC H03H 9/02259; H03H 9/171; H03H 2009/02503; H03H 2009/155

(57) ABSTRACT

A piezoelectric Micro-Electro-Mechanical Systems (MEMS) resonator employs a thin-film piezoelectric layer as an anchor, which eliminates a dominant loss source, anchor loss, which stems from the irreversible mechanical energy radiation through the anchors. By implementing fundamental or higher-order thickness Lame modes (TLMs) in the thickness direction, the piezoelectric resonator exhibits a substantial reduction of thermoelastic damping (TED) and increase of anchor quality factor. The piezoelectric resonator also provides temperature stability by utilizing a substrate with a turnover temperature, minimizing deviation on resonance frequency. This approach enables the use of thin-film piezoelectric materials as anchors, which can be precisely controlled to minimize losses. The piezoelectric resonator's compact design and CMOS-compatibility make it suitable for batch production at a minimal cost per unit. Furthermore, the highly frequency-stable temperature point of the piezoelectric resonator can be used for implementing oven-controlled oscillators for ultra-stable clock generation in various applications.

### BACKGROUND

Timing applications typically involve precise frequency control, which is conventionally achieved using quartz resonators. However, these conventional solutions have limitations, including high cost, large size, and limited flexibility. Micro-Electro-Mechanical Systems (MEMS) resonators offer a promising alternative, providing low cost, small size, and high performance. Specifically, MEMS resonators can be designed to operate at frequencies suitable for timing applications. Despite their advantages, commercial MEMS resonators, have limitations that prevent them from fully replacing quartz resonators. One issue with such MEMS resonators is temperature stability. Quartz resonators exhibit excellent temperature stability, which is useful for many timing applications. In contrast, MEMS resonators can be sensitive to temperature fluctuations, leading to frequency drift and reduced accuracy. Another challenge facing MEMS resonators is noise performance. Conventional quartz resonators have very low noise floors, making them suitable for demanding timing applications. However, commercial MEMS resonators are typically capacitively driven, which results in higher loss and increased power consumption. This not only reduces their overall performance but also limits their ability to fully replace quartz resonators. Piezoelectrically driven MEMS resonators offer another alternative, as they can provide lower loss and potentially better noise performance compared to capacitive driving schemes. However, these devices exhibit temperature stability and noise performance that should be addressed before they can be considered viable replacements for both quartz and current capacitive MEMS solutions.

### BRIEF DESCRIPTION THE DRAWINGS

FIG. 1 illustrates a perspective view of a topside of a piezoelectric Micro-Electro-Mechanical Systems (MEMS) resonator implementing a thickness Lamé mode (TLM) with thin-film anchors for minimized anchor loss in accordance with some embodiments.

FIG. 2 illustrates a perspective backside view of the piezoelectric MEMS resonator of FIG. 1, further illustrating the suspended resonant body and thin-film anchoring structures in accordance with some embodiments.

FIG. 3 illustrates a schematic of a conventional resonator anchoring configuration that contributes to substantial anchor loss.

FIG. 4 illustrates a schematic of the piezoelectric MEMS resonator of FIG. 1, showing thin-film anchors positioned at minimal-displacement nodal points defined by an illustrated mode shape to minimize anchor loss in accordance with some embodiments.

FIG. 5 illustrates an example frequency response (admittance characteristic) for the piezoelectric MEMS resonator of FIG. 1 in accordance with some embodiments.

FIG. 6 illustrates simulation results of a conventional piezoelectric MEMS resonator depicting anchor loss associated with a fundamental TLM

FIG. 7 illustrates simulation results of an a piezoelectric MEMS resonator implementing a fundamental TLM with a thin-film anchor configuration in accordance with some embodiments.

FIG. 8 illustrates simulation results of a piezoelectric MEMS resonator implementing a higher-order thickness TLM with a thin-film anchor configuration in accordance with some embodiments.

FIG. 9 illustrates simulation results of a piezoelectric MEMS resonator incorporating phononic crystals integrated into the thin-film anchor configuration in accordance with some embodiments.

FIG. 10 illustrates simulated higher-order TLM shapes achievable with the thin-film anchor configurations and minimal displacement nodal anchoring points in accordance with some embodiments.

FIG. 11 illustrates additional simulated higher-order TLM shapes achievable with thin-film anchor configurations in accordance with some embodiments.

FIG. 12 illustrates a top-down schematic view of a piezoelectric MEMS resonator structure showing a thin-film piezoelectric layer configuration with selectively etched openings for mechanical isolation and minimal displacement anchoring in accordance with some embodiments.

FIG. 13 illustrates a cross-sectional view taken along line A-A of FIG. 12, depicting the structural isolation and suspension of the resonant body via etched gaps and thin-film anchors in accordance with some embodiments.

FIG. 14 illustrates another cross-sectional view of the piezoelectric MEMS resonator of FIG. 12 including an additional structural and/or functional layer underlying the thin-film piezoelectric layer to enhance mechanical support and acoustic isolation in accordance with some embodiments.

FIG. 15 illustrates a further cross-sectional view of the piezoelectric MEMS resonator of FIG. 12 in which an additional structural and/or functional layer is positioned atop peripheral substrate regions, providing enhanced mechanical robustness at anchor points in accordance with some embodiments.

FIG. 16 illustrates another cross-sectional view of the piezoelectric MEMS resonator of FIG. 12 with multiple structural and/or functional layers positioned above and below the thin-film piezoelectric layer in accordance with some embodiments.

FIG. 17 illustrates a top-down view of a piezoelectric MEMS resonator configured with an integrated silicon-on-insulator (SOI) heater layer in accordance with some embodiments.

FIG. 18 illustrates a cross-sectional view taken along line B-B of FIG. 17, depicting the SOI heater layer integrated beneath the thin-film piezoelectric layer in accordance with some embodiments.

FIG. 19 illustrates a top-down view of a piezoelectric MEMS resonator having substrate regions with tailored doping profiles in accordance with some embodiments.

FIG. 20 illustrates a cross-sectional view taken along line A-A of FIG. 19, depicting substrate portions with distinct doping profiles in accordance with some embodiments.

FIG. 21 illustrates both top and cross-sectional views depicting an initial fabrication step for a piezoelectric MEMS resonator implementing a TLM with thin-film anchors in accordance with some embodiments.

FIG. 22 illustrates both top and cross-sectional views of a fabrication step subsequent to the fabrication step of FIG. 21 in accordance with some embodiments.

FIG. 23 illustrates both top and cross-sectional views of a fabrication step subsequent to the fabrication step of FIG. 22 in accordance with some embodiments.

FIG. 24 illustrates top-down views of various example configurations of etched structures and segmented piezoelectric layer arrangements for a piezoelectric MEMS resonator implementing a TLM with thin-film anchors in accordance with some embodiments.

FIG. 25 illustrates a cross-sectional side view of an oscillator arrangement incorporating a thin-film piezoelectric MEMS resonator die integrated with an electronics die and positioned on an interposer in accordance with some embodiments.

FIG. 26 illustrates a cross-sectional side view of an example configuration for packaging arrangement for a piezoelectric MEMS resonator implementing a TLM with thin-film anchors in accordance with some embodiments.

FIG. 27 illustrates an operational flow diagram illustrating one example of a process for fabricating a thin-film piezoelectric MEMS resonators in accordance with some embodiments.

### DETAILED DESCRIPTION

MEMS resonators, increasingly used as replacements for quartz crystal resonators in timing and clock applications, provide significant advantages, including a smaller physical size and reduced sensitivity to external vibrations. However, conventional MEMS resonators typically rely on capacitive driving, a method where an electrical field between closely spaced electrodes induces mechanical vibrations. Capacitive driving, while widely used, is inherently inefficient for converting electrical energy into mechanical energy due to the relatively weak coupling between electrical input and mechanical output. This inefficiency manifests as higher motional resistance, which is defined as the electrical impedance presented by the resonator when vibrating at resonance, and results in increased power consumption when these resonators are used in oscillators (circuits configured to produce a stable periodic signal). Consequently, there has been significant interest in developing piezoelectrically driven MEMS resonators, as piezoelectric materials inherently provide stronger electromechanical coupling, enhancing the efficiency of energy conversion. However, one notable drawback of piezoelectric MEMS resonators is their relatively low quality factor (Q), a dimensionless parameter that characterizes the resonator's energy storage efficiency compared to energy lost per oscillation cycle. A low quality factor limits oscillator performance by increasing phase noise (unwanted fluctuations in signal timing), thus reducing the stability of generated clock signals. In piezoelectric MEMS resonators, two dominant sources significantly impact the quality factor and introduce noise: anchor loss, which refers to the irreversible escape of mechanical (acoustic) energy through structural supports or anchors, and thermoelastic damping (TED), which involves the dissipation of mechanical energy through heat transfer between thermally compressed and expanded regions within the resonator body.

Lamé mode resonators, particularly thickness Lamé mode (TLM) resonators, offer distinct operational advantages due to their isochoric characteristics, which means they conserve volume during mechanical vibrations. This volumetric conservation substantially reduces or eliminates thermoelastic damping, as TED inherently relies on thermal gradients arising from volume changes within the resonator structure. The inherent elimination of TED makes Lamé mode resonators especially suitable for timing applications requiring stable and precise frequency outputs. Despite this advantage, conventional implementations of piezoelectric Lamé mode resonators suffer significantly from anchor loss. Specifically, planar Lamé mode resonators, traditionally anchored at multiple points (often from four corners), typically cannot be efficiently excited when employing aluminum nitride, the piezoelectric material predominantly used in industry-standard MEMS fabrication processes. Furthermore, previous demonstrations of thickness Lamé mode resonators have commonly utilized anchors spanning the entire resonator thickness. Such anchoring methods do not exploit zero displacement nodes (regions within the resonator where mechanical displacement is minimal or nonexistent), thereby contributing significantly to anchor loss and severely limiting the attainable Q and overall resonator performance.

To overcome these challenges, the following describes embodiments of a resonator configured to address the performance limitations described above, including poor temperature stability and compromised noise performance. The resonator of one or more embodiments disclosed herein is a piezoelectric resonator implemented as a thin-film (TF) suspended microacoustic resonator. “Thin-film” refers to layers of materials deposited in thicknesses typically on the order of nanometers (nm) to micrometers (μm). These thin-film resonators are fabricated on substrates composed of low-loss materials, such as silicon or silicon carbide, selected for their favorable mechanical and thermal properties. Furthermore, these substrates are compatible with complementary metal-oxide-semiconductor (CMOS) technology, which is a widely adopted semiconductor fabrication technique enabling integration of electronic circuits on the same substrate, making the resonator readily integrable into existing electronic systems.

The piezoelectric resonator described herein achieves exceptional quality factors (low noise characteristics) along with outstanding temperature stability, suitable for high-performance and other timing applications. In some embodiments, the thin-film piezoelectric material (e.g., aluminum nitride, lithium niobate, lithium tantalate, lead zirconate titanate (PZT), or lead magnesium niobate-lead zirconate titanate (PMN-PT)) provides a dual purpose. For example, the thin-film piezoelectric material functions as both an efficient excitation mechanism for the underlying low-loss substrate material and as an anchor that mechanically supports the resonant body. In at least some embodiments, this anchoring is implemented only at designated zero-displacement nodes, which are chosen points in the resonant structure where mechanical displacement is minimal (below a specified threshold) or zero during oscillation.

By anchoring exclusively at these points, one or more embodiments disclosed herein effectively mitigate anchor loss, thereby fully leveraging the intrinsic low-loss properties of the chosen substrate material. Additionally, these substrates are economical, enabling cost-effective mass production and enhancing the commercial attractiveness of the described resonators. By combining the high quality factor typically found in capacitive MEMS resonators (due to minimized anchor loss) with the inherently low-loss excitation offered by piezoelectric materials, the disclosed piezoelectric resonator provides a highly advantageous solution for advanced timing and clock applications. Furthermore, the described piezoelectric resonator utilizes thickness Lamé mode acoustic resonances, further capitalizing on their inherent isochoric (volume-conserving) properties to eliminate thermoelastic damping. The implementation of thin-film anchors configured to support the thickness Lamé mode resonant body significantly reduces anchor loss, enabling oscillators utilizing these resonators to achieve extremely low phase noise performance.

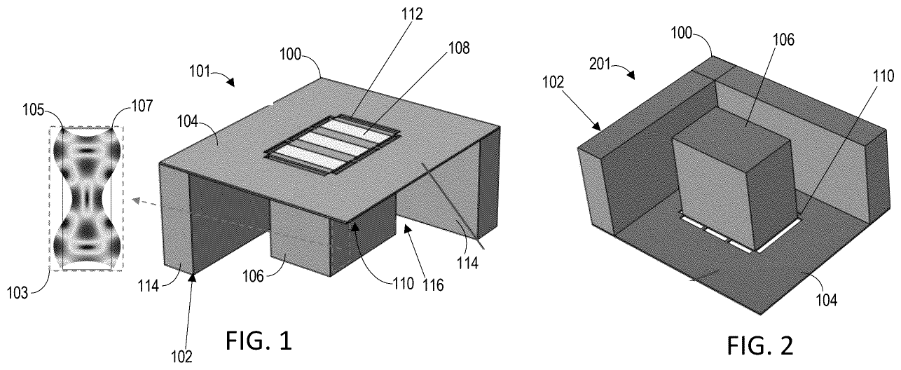

FIG. 1 shows a first perspective view of a topside 101, and FIG. 2 shows a second perspective view of a backside 201, of a piezoelectric MEMS resonator 100 (also referred to herein as a “piezoelectric resonator 100” for brevity) in accordance with one or more embodiments. In one or more embodiments, the piezoelectric resonator 100 shown in FIG. 1 includes a resonant or resonating structure comprising a relatively thick (e.g., 300-600 micrometers (μm)), low-loss substrate 102 with an overlaying thin-film piezoelectric layer 104. As used herein, the terms “resonant structure” and “resonating structure” refer to the complete MEMS resonator assembly, including the resonant body 106, substrate 102, electrodes 108, thin-film piezoelectric layer 104, and associated anchors 110, while the term “resonant body” refers to the central vibrating portion of this structure. A “low-loss substrate”, as used herein, refers to substrate materials exhibiting low acoustic (mechanical) energy loss characteristics. In at least some embodiments, suitable substrate materials include silicon, silicon carbide, diamond, sapphire, or similar materials known to have low mechanical loss. The piezoelectric resonator 100 further includes a resonant body 106, which, in at least some embodiments, is formed from at least a portion of the low-loss substrate 102, the thin-film piezoelectric layer 104, and one or more electrodes 108.

The electrodes 108 are illustrated in FIG. 1 being disposed on top of the thin-film piezoelectric layer 104 and are configured to apply an electric field across the piezoelectric layer 104, thereby converting electrical signals into mechanical vibrations and vice versa. The thin-film piezoelectric layer 104, in at least some embodiments, comprises piezoelectric materials such as aluminum nitride (AlN), lithium niobate (LiNbO₃), lithium tantalate (LiTaO₃), lead zirconate titanate (PZT), lead magnesium niobate-lead zirconate titanate (PMN-PT), or alloyed/doped variants thereof. As such, the thin-film piezoelectric layer 104 provides a transduction mechanism, meaning it converts electrical signals into mechanical vibrations and senses mechanical vibrations by converting them back into electrical signals. In addition, the thin-film piezoelectric layer 104 functions as an anchor, suspending and mechanically coupling the resonant body 106 to the substrate 102 at specific anchoring points 110, thereby minimizing anchor loss.

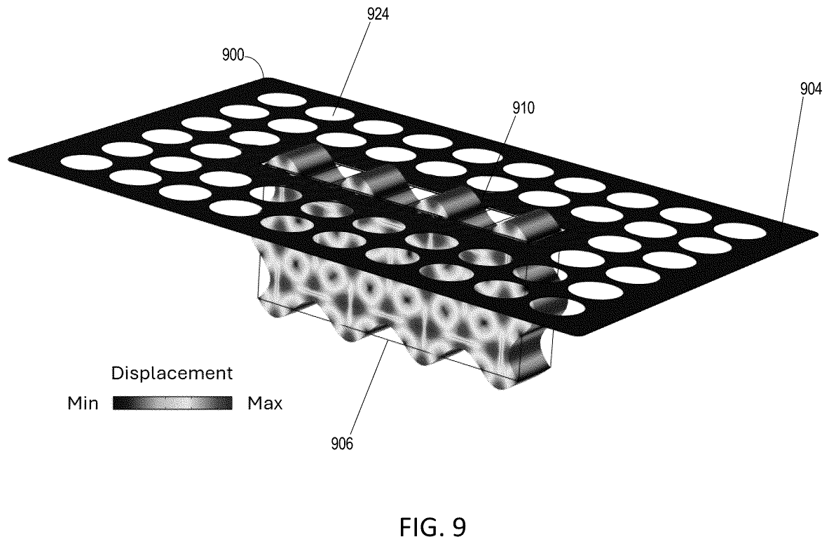

For instance, FIG. 1 illustrates that the thin-film piezoelectric layer 104 suspends the resonant body 106 at its zero-displacement points 110 (nodes), represented by the blue colored areas at corners 105, 107 within the mode shape 103 outlined by the dashed rectangle. These zero-displacement nodes 110 correspond to peripheral corner regions of the resonant body 106, defining areas of minimal mechanical motion during resonance, thereby reducing mechanical energy loss. FIG. 1 also shows patterned etched regions or openings 112 within the thin-film piezoelectric layer 104. These patterned etched regions or openings 112 represent isolation features or electrode-defining structures configured to electrically and mechanically isolate portions of the piezoelectric layer 104, define electrode geometry, optimize electromechanical coupling, and enhance overall resonator performance. Additionally, in at least some embodiments, the thin-film piezoelectric layer 104 further incorporates phononic crystals, which can be formed as periodic arrangements of patterned openings, voids, or other structural features specifically engineered to introduce acoustic bandgap effects. These phononic crystals effectively prevent or significantly reduce acoustic energy transmission, further reducing anchor loss and enhancing the acoustic isolation and overall resonator quality factor, as described in greater detail with reference to FIG. 9 below.

In at least some embodiments, the resonant body 106 is suspended within surrounding substrate support regions 114, which represent portions of the substrate 102 not etched away during fabrication. These substrate support regions 114 at least partially surround the resonant body 106 and provide structural integrity, mechanical support, and facilitate stable anchoring to the overall device structure. Additionally, as illustrated, a gap 116 separates the resonant body 106 from the surrounding substrate support regions 114, ensuring that the resonant body 106 remains mechanically isolated and free to vibrate without significant acoustic coupling or energy leakage into the substrate, further enhancing performance by reducing anchor loss and associated noise.

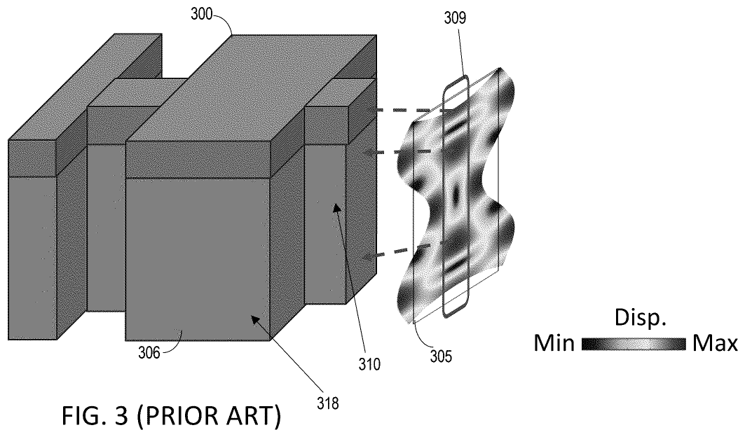

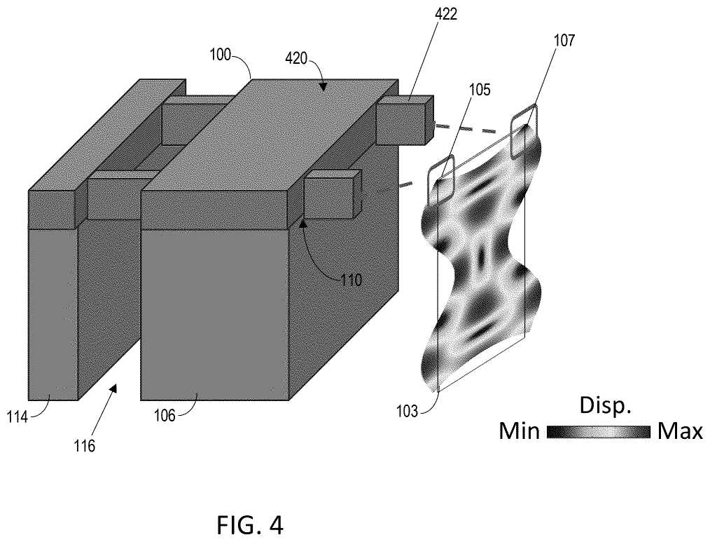

The anchoring configuration of the piezoelectric resonator 100 of one or more embodiments addresses the long-standing problem of increased noise in piezoelectric MEMS resonators due to anchor loss. Anchor loss refers to the irreversible leakage of acoustic energy from the resonant body through its anchoring points into surrounding support structures, thereby reducing resonator quality factor (Q) and introducing undesirable noise into the oscillator signal. FIGS. 3 and 4 illustrate simplified comparative examples demonstrating this structural difference. In conventional resonators, such as the resonator 300 depicted in FIG. 3, anchor regions 310 extend fully across the entire thickness of the resonant structure 318. These anchor regions 310, represented by the outlined area 309 of the displacement mode shape 305, mechanically couple the resonant body 306 directly to adjacent substrate regions. As illustrated by the dashed arrows, the anchor regions 310 connect directly to locations of significant mechanical displacement, which are indicated by the red shaded areas in the displacement mode shape 305 to which the dashed arrows point. Such placement of anchor regions 310 in areas of high displacement results in substantial acoustic energy coupling into the substrate, causing significant anchor loss, reduced quality factor (Q), and degraded resonator performance.

In contrast, the piezoelectric resonator 100 of one or more embodiments illustrated in FIG. 4 replaces these conventional anchor regions 310 with thin-film anchors 110 formed exclusively by the thin-film piezoelectric layer 104, as previously described with respect to FIG. 1 and FIG. 2. These thin-film anchors 110 connect only the top portion 420 (with reference to the orientation shown in FIG. 1 and FIG. 4) of the resonant body 106 to the surrounding substrate support regions 114 at zero-displacement points 422. This optimized anchoring configuration is illustrated by the dashed lines in FIG. 4, which identify the regions of minimal mechanical displacement (nodal points) on the resonant body 106. These zero-displacement nodal points 422 correspond to the blue shaded areas 105, 107 shown in the displacement mode shape 103. By positioning thin-film anchors 110 exclusively at these zero-displacement regions, anchor loss is substantially reduced. Additionally, the gap 116 described above with respect to FIGS. 1 and 2 ensures mechanical isolation between the resonant body 106 and substrate support regions 114, further minimizing unwanted acoustic coupling and energy leakage into surrounding structures. This improved anchoring configuration translates directly into reduced phase noise (timing fluctuations in oscillator signals), higher resonator quality factor, and enhanced overall resonator performance, making the disclosed design particularly advantageous for acoustic modes characterized by inherently low thermoelastic damping (TED), such as TLMs.

As described above, TLM resonators exhibit isochoric characteristics, meaning they conserve volume during resonance, which eliminates thermoelastic damping as a significant loss mechanism in MEMS resonators operating in frequency ranges typically spanning from megahertz (MHz) to gigahertz (GHz). However, TLM resonators inherently present challenges regarding anchor loss due to their unique displacement profiles. For example, TLM resonators exhibit displacement nodes only at their corners and centers, limiting the ability to effectively use conventional full-thickness anchors. Consequently, traditional anchoring configurations result in excessive energy leakage and diminished resonator quality factor (Q). Advantageously, the piezoelectric resonator 100 described herein supports the TLM resonant body 106 through its top corner nodal points using the thin-film piezoelectric layer 104 as anchors. These thin-film anchors 110 bridge the resonant body 106 exclusively at carefully selected zero-displacement regions, leaving a gap 116 to separate the resonant body 106 from surrounding substrate support regions 114. This anchoring configuration significantly reduces anchor loss and mechanically isolates the resonant body, enabling high-performance MEMS devices with exceptionally low noise and stable frequency outputs.

Additionally, in at least some embodiments, the piezoelectric resonator 100 implements higher-order TLM resonances in the thickness direction. Higher-order resonances refer to resonant modes having more complex displacement patterns and increased nodal points across the thickness and lateral directions of the resonant body. Utilizing higher-order resonances enables a proportional increase in the resonant body's thickness, thereby maintaining the resonance frequency while utilizing a larger portion of low-loss substrate material. Moreover, the piezoelectric resonator 100, in at least some embodiments, achieves temperature stability by implementing substrates formed from materials characterized by a turnover temperature. A “turnover temperature” is a specific temperature at which the resonator material exhibits a zero temperature coefficient of frequency (TCF), meaning temperature fluctuations around this point minimally affect resonance frequency. For example, thickness Lamé mode resonators fabricated from degenerately doped silicon can achieve turnover temperatures above 80° C., making them highly suitable for implementing oven-controlled MEMS oscillators, which are MEMS-based equivalents of conventional Oven-controlled Crystal Oscillators (OCXOs).

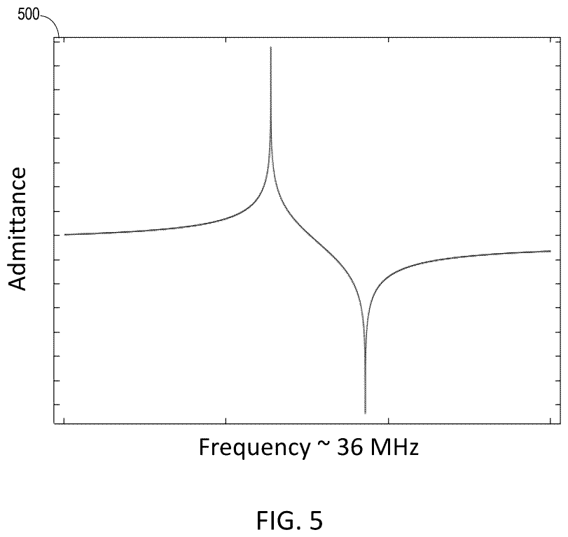

Having described at least some of the structural and anchoring advantages of the disclosed piezoelectric MEMS resonators in FIGS. 1 through 4, FIG. 5 provides an example of a practical illustration of their electromechanical resonance characteristics. In particular, FIG. 5 depicts an example frequency response (admittance) 500 of a piezoelectric MEMS resonator, such as resonator 100. In particular, FIG. 5 shows the admittance characteristic of a third-order TLM resonator operating at approximately 36 MHz. The illustrated resonator embodiment corresponds, for example, to a structure having a relatively thick block of silicon (e.g., approximately 300 μm thick), combined with a thin-film piezoelectric layer (e.g., approximately 2 μm thick) of AlN, consistent with the resonators described previously herein. FIG. 5 demonstrates the resonator's characteristic frequency response, highlighting a resonant behavior suitable for implementing high-quality, low-noise oscillators at this frequency. The resonance peaks and dips illustrated in FIG. 5 correspond directly to the electromechanical resonant modes described previously. These frequency response characteristics particularly benefit from the minimized anchor loss achieved by the thin-film anchoring configuration disclosed in FIGS. 1 through 4, verifying the resonator's suitability for applications such as stable frequency references, precision timing circuits, and low-power real-time clocks.

Additionally, FIG. 5 demonstrates the advantageous scaling properties of the resonators disclosed herein, wherein changing substrate thickness and thickness mode order proportionally scales the resonant frequency. For instance, a second thickness-order resonator operating at approximately 12 MHz can be realized by increasing the substrate thickness to about 600 μm, maintaining similar device footprints and fabrication compatibility. In other embodiments, electromechanical coupling and resulting resonator performance can be further enhanced by selecting alternative piezoelectric materials, including doped or alloyed variants of aluminum nitride, lithium niobate, lithium tantalate, PZT, or PMN-PT, or by using a thicker piezoelectric layer relative to the acoustic wavelength. Electrodes can be positioned on either or both sides of the piezoelectric layer to facilitate lateral and/or thickness-field excitation of the resonant body.

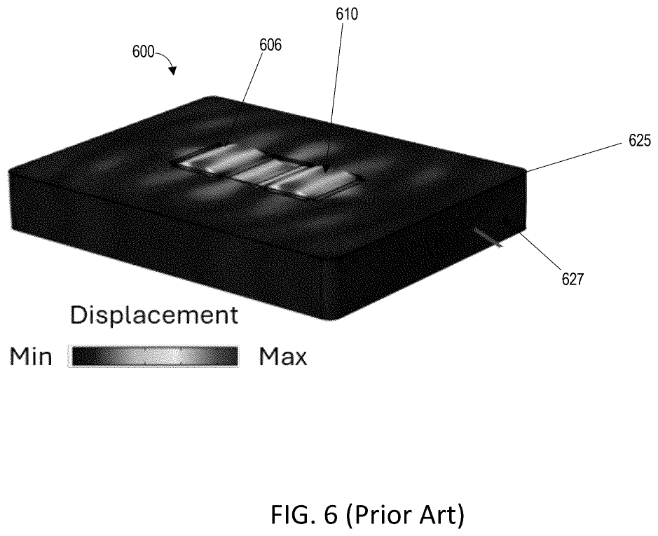

FIG. 6 to FIG. 9 illustrate a simplified comparative example of another piezoelectric resonator according to one or more embodiments, implementing a fundamental thickness TLM resonance, compared to a conventional piezoelectric resonator suffering from high anchor loss. FIGS. 6 to 9 additionally represent simulation results (e.g., finite element method (FEM) simulations) performed to illustrate the differences in anchor loss between conventional and improved resonator configurations. The simulations employed a low-reflecting boundary condition at the outer edges to realistically simulate acoustic energy leakage, preventing artificial reflections and thus accurately quantifying anchor loss. In these simulation illustrations, the surrounding substrate regions, depicted in dark blue, support the resonant body, depicted in a gradient rainbow pattern representing mechanical displacement intensity. Anchors connecting the resonant body to the surrounding substrate are not explicitly visible due to the illustrated viewing angle and their relatively small size compared to other depicted elements.

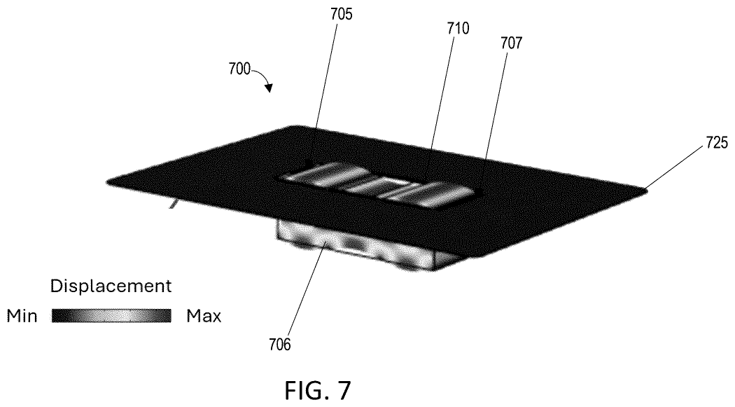

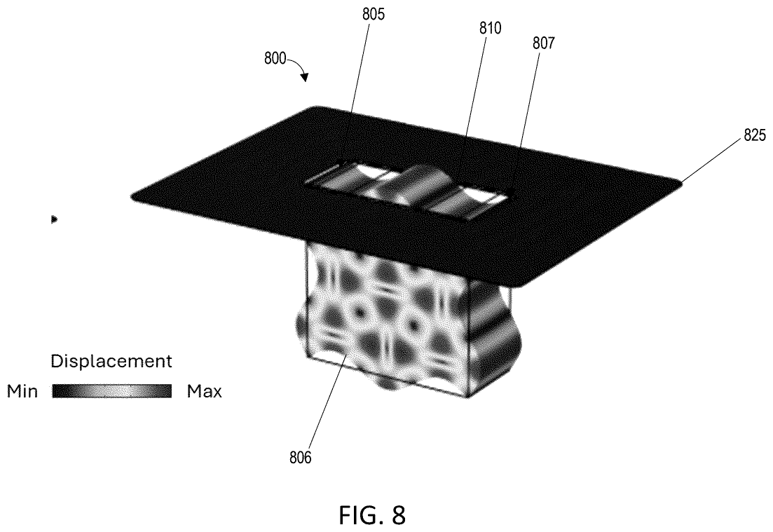

FIG. 6 depicts a conventional piezoelectric MEMS resonator 600 operating in a fundamental thickness mode (1st thickness mode, 3rd lateral order), comprising a resonant body 606 mechanically coupled to substrate regions by conventional anchor regions 610. For anchor loss simulations, the boundary condition on the outer edge of the rectangle 625 surrounding the resonant body is a low-reflective boundary 627. The anchor regions 610 extend fully across the entire thickness of the resonant structure and directly connect the resonant body 606 to the substrate. Due to these anchor regions 610 spanning areas of high mechanical displacement, significant anchor loss occurs, causing leakage of acoustic energy into the substrate and substantially reducing the resonator's quality factor (Q) and overall performance. The high mechanical displacement in FIG. 6 is represented by the lighter shades of blue (escaped acoustic waves) seen in the rectangle surrounding the resonant body 606 compared to the dark blue shade seen in the rectangle 725 surrounding the resonant body 706 in FIG. 7 and the rectangle 825 surrounding the resonant body 806 in FIG. 8.

Both FIGS. 7 and 8 illustrate simulated mechanical displacement patterns within the resonant body 706, 806, highlighting minimal displacement regions (represented by the dark blue shaded areas), referred to herein as anchor regions 710, 810 that correspond to anchoring locations of interest. These figures demonstrate how anchor loss can be substantially reduced by positioning thin-film anchors exclusively at these anchor regions 710, 810. Unlike the conventional anchor regions 610 shown in FIG. 6, the anchor regions 710, 810 (not explicitly depicted as physical structures in FIGS. 7 and 8) of resonator 700 and resonator 800 are intended to be formed from a thin-film piezoelectric layer disposed on the top portion (with respect to the orientation of FIGS. 7 and 8) of the resonant body 706, 806 providing mechanical support only at minimal displacement regions. These anchor regions 710, 810 are separated from adjacent structures by gaps (conceptually similar to gap 116 described previously), indicating mechanical isolation and significantly minimizing acoustic energy transfer. For clarity, structural elements such as the substrate regions (previously described in relation to FIGS. 1 to 4), the thin-film piezoelectric layer, and electrodes are not illustrated in these schematic simulation figures (FIGS. 7 and 8), which instead show internal mechanical displacement patterns and identifying optimal anchoring positions within the resonant body 706, 806. Also, the dark blue shade in the rectangular regions 725, 825 surrounding the resonant bodies 706 and 806 shown in FIGS. 7 and 8 represent minimal displacement (zero-displacement) regions, compared to the lighter blue shades in the rectangular region 625 surrounding the resonant body 606 depicted in FIG. 6, representing heavy-displacement.

The schematic illustrations depicted in FIGS. 7 and 8 visually clarify the improved anchoring strategy by showing resonator structures with simulated internal mechanical displacement patterns. Both figures illustrate displacement patterns within resonant bodies 706 and 806, respectively, with blue shaded corners 705, 707 (FIG. 7) and 805, 807 (FIG. 8) identifying minimal displacement regions (zero-displacement nodal points). These nodal points correspond to optimal positions for thin-film anchors. By anchoring the resonant bodies 706, 806 exclusively at these minimal displacement points, the piezoelectric resonator 700, 800 significantly reduces anchor loss. The fundamental thickness Lame mode (TLM) depicted in FIG. 7 achieves the lowest resonance frequency, making it particularly beneficial for timing applications requiring low-frequency, high-performance MEMS clocks. Higher-order thickness modes, such as the 3rd thickness TLM depicted in FIG. 8, further reduce anchor loss by providing additional minimal displacement regions suitable for anchoring, and, therefore, may be advantageous for applications demanding even lower anchor loss and higher quality factors. Such applications include, but are not limited to, real-time clocks, frequency references, and other precision timing systems where low noise and stable resonance frequency are desired.

Furthermore, FIGS. 6 to 8 illustrate simulated anchor quality factors (Q_anchor, which is inversely proportional to anchor loss), showing significant improvement obtained by the thin-film anchor configuration of one or more embodiments. For example, the conventional resonator 600 in FIG. 6 exhibits an anchor quality factor Q_anchor of less than 50,000, indicative of very high anchor loss and limited resonator performance. In contrast, the improved piezoelectric resonator 700 implementing the fundamental thickness mode (1st thickness, 3rd lateral order) shown in FIG. 7 achieves a significantly enhanced anchor quality factor of approximately 320,000. Further improvement is illustrated by the higher-order thickness mode (3rd thickness, 3rd lateral order) of the piezoelectric resonator 800 shown in FIG. 8, which achieves an even higher anchor quality factor of approximately 650,000. These simulated results demonstrate the substantial benefit of the disclosed thin-film anchor configuration and highlight the additional anchor-loss reduction obtainable by using higher-order thickness modes.

The improved resonator structures in FIGS. 7 and 8 lack the thick anchor regions 610 shown in FIG. 6 between the resonant body and surrounding substrate, demonstrating significantly reduced acoustic energy leakage and improved acoustic isolation achieved through the thin-film anchor 710, 810 configuration. The absence of thick, full-thickness substrate anchors in FIGS. 7 and 8 results from the placement of thin-film anchors 710 exclusively at minimal-displacement nodes, depicted by the thin rectangular minimal-displacement regions surrounding the resonant bodies 706, 806, thereby substantially reducing anchor loss and greatly increasing the resonator's anchor Q.

Thus, FIGS. 6 to 8 illustrate the structural and functional advantages of the piezoelectric resonator of one or more embodiments, highlighting the placement of thin-film anchors 710, 810 at zero-displacement regions, significantly mitigating anchor loss and enabling high-quality, low-noise, and mechanically isolated MEMS resonators suitable for advanced timing applications. Additionally, these simulations confirm that further increases in thickness mode order, from the fundamental thickness mode illustrated in FIG. 7 (fundamental thickness, 3rd lateral order) to a higher-order thickness mode illustrated in FIG. 8 (higher-order (3rd thickness), 3rd lateral order), can further enhance anchor quality factor and resonator performance, beneficially optimizing resonator characteristics for specific application requirements.

FIG. 9 illustrates yet another embodiment that provides further improvements in anchor quality factor (Q_anchor). For example, FIG. 9 depicts a FEM simulation of a piezoelectric MEMS resonator 900 configured in a third thickness, seventh lateral mode (3×7), integrating the previously described thin-film anchor configuration with additional phononic crystals 924 to achieve even greater reduction in anchor loss. The phononic crystals 924 shown in FIG. 9 are implemented as a patterned arrangement of dimensioned and positioned holes or voids formed within or adjacent to the thin-film suspension layer 904. Such phononic crystals 924 introduce engineered acoustic bandgap structures that further prevent acoustic energy from escaping through the anchors (represented as anchor regions 910 in FIG. 9), thus significantly improving mechanical isolation and enhancing the anchor quality factor. As indicated in FIG. 9, incorporating phononic crystals 924 in conjunction with the disclosed thin-film anchor configuration can achieve anchor quality factors greater than approximately 2,000,000 (Q_anchor>2 million), representing a substantial and highly advantageous improvement over both conventional configurations. The depicted displacement pattern in FIG. 9 clearly demonstrate minimal displacement at anchoring regions 910, verifying the efficacy of this combined approach in substantially suppressing anchor loss. Such extremely high anchor quality factors achieved through the addition of phononic crystals 924 make this configuration especially advantageous for the most demanding timing applications, including ultra-stable frequency references, high-precision navigation systems, telecommunications, and other scenarios requiring minimal phase noise and exceptional frequency stability.

As such, the simulations illustrated in FIG. 6 to FIG. 9 demonstrate the effectiveness of the thin-film anchor configuration described herein. Anchor quality factor (Q_anchor), defined as approximately the inverse of anchor loss (Q_anchor˜1/Loss_anchor), is substantially increased, pushing resonator performance towards material-limited losses. Achieving these material-limited losses enables the creation of oscillators characterized by extremely low phase noise, which is an advantageous attribute for advanced timing and frequency reference applications. Moreover, the described piezoelectric MEMS resonator structures are advantageously configured to be compact, typically occupying a footprint of, for example, approximately 1 square millimeter or less, thus enabling integration into miniaturized electronic systems. Additionally, the resonator structures are configured to be fabricated on low-cost and CMOS-compatible substrates, thereby offering significant practical advantages in terms of manufacturability, cost-effectiveness, and ease of integration with existing semiconductor fabrication processes.

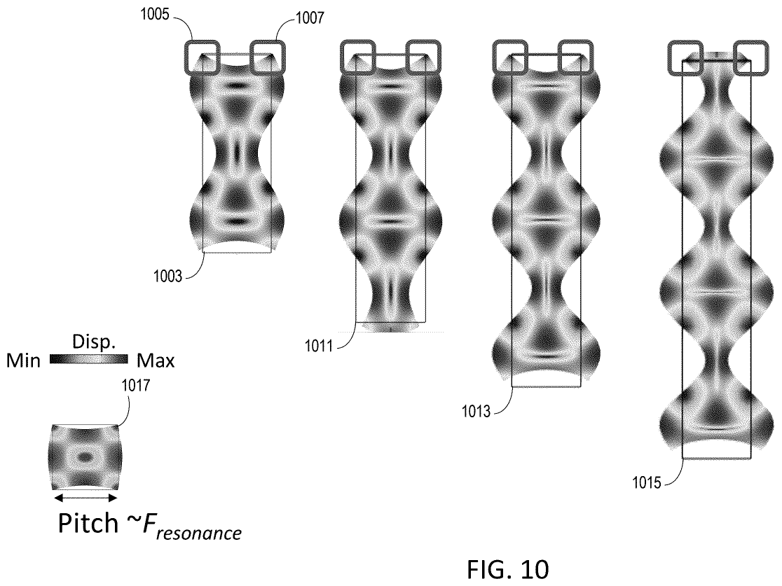

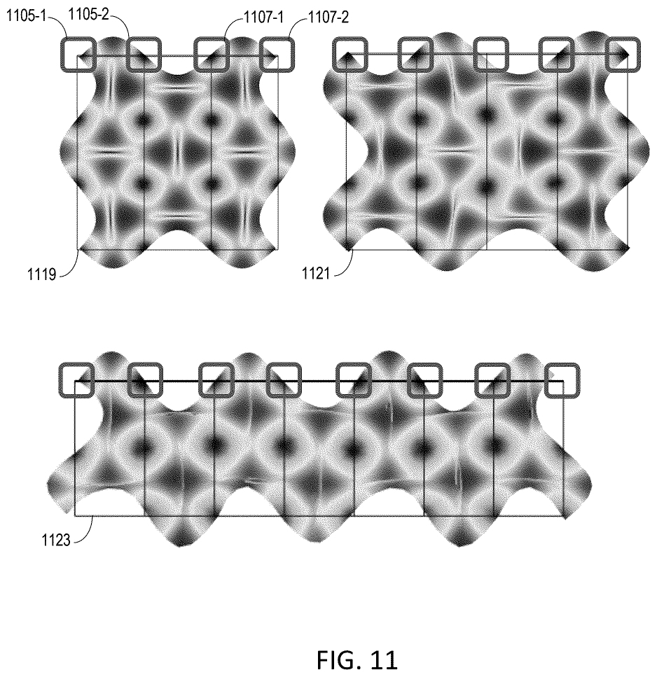

FIG. 10 and FIG. 11 illustrate further examples of simulated mode shapes representing additional higher-order TLM resonances that can be achieved by employing the piezoelectric MEMS resonator structures described herein. These figures depict FEM simulated cross-sectional views of representative thickness and lateral mode orders that can be effectively excited and anchored utilizing the thin-film anchor configurations discussed previously with reference to FIGS. 1, 2, 4, and 6 to 9. FIG. 10 provides FEM-simulated cross-sectional mode shapes of exemplary higher-order TLMs, including a thickness 3rd lateral 1st mode (mode shape 1003), a thickness 4th lateral 1st mode (mode shape 1011), a thickness 5th lateral 1st mode (mode shape 1013), and a thickness 6th lateral 1st mode (element 1015). Each illustrated mode shape in FIG. 10 depicts internal mechanical displacement patterns represented by varying patterns, with blue shaded regions corresponding to minimal mechanical displacement (zero-displacement nodal points), and red shaded regions indicating areas of maximal mechanical displacement. The dashed boxes (labeled as 1005, 1007 only in mode shape 1013 for brevity) highlight these minimal displacement nodal regions, identifying them as optimal anchoring locations corresponding to the thin-film anchor placements described previously. Anchoring at these nodal points significantly reduces anchor loss and acoustic energy leakage, substantially enhancing the anchor quality factor (Q_anchor) and overall resonator performance. Additionally, FIG. 10 illustrates how the pitch dimension 1017, representing the lateral dimension of the resonant body, such as resonant body 106, can be proportionally scaled together with substrate thickness to maintain or adjust resonance frequency as the thickness and lateral mode orders are increased. Such proportional scaling enables precise tuning and optimization of resonator frequency characteristics to meet diverse application-specific requirements.

FIG. 11 similarly presents FEM-simulated cross-sectional mode shapes representing more complex higher-order thickness and lateral Lamé modes. The illustrated examples include a thickness 3rd lateral 3rd mode (mode shape 1119), a thickness 3rd lateral 4th mode (mode shape 1121), and a thickness 2nd lateral 7th mode (mode shape 1123). As in FIG. 10, FIG. 11 employs displacement patterns, with blue shaded areas representing minimal displacement nodal regions and red shaded areas denoting maximal displacement. The dashed boxes (labeled as 1105-1, 1105-2, 1107-1, 1107-2 only in mode shape 1119 for brevity) again highlight minimal displacement nodal regions positioned at or near the upper surfaces and corners of each resonant body, marking ideal locations for thin-film anchors. The increased complexity and number of nodal points provided by these higher-order modes advantageously offer additional anchoring locations, further mitigating anchor loss and thus enabling even higher anchor quality factors (Q_anchor) and improved resonator stability and performance.

Thus, the simulated mode shapes illustrated in FIGS. 10 and 11 illustrate the broad versatility and efficacy of the thin-film anchor configuration and piezoelectric MEMS resonator structures described herein. These results highlight the capability of the disclosed configurations to support various higher-order thickness and lateral Lamé modes, thereby providing tailored resonator designs suitable for advanced MEMS timing devices, ultra-stable frequency references, and precision frequency-controlled systems demanding minimal phase noise and exceptional frequency stability.

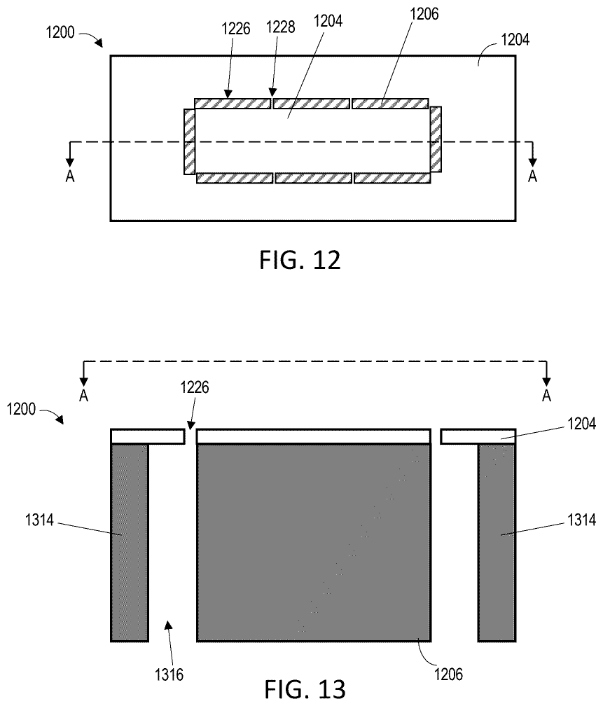

Referring now to FIGS. 12 to 16, these figures illustrate various configurations of one or more thin-film piezoelectric MEMS resonators disclosed herein, highlighting the structural arrangements of resonant bodies, piezoelectric layers, and additional functional or structural layers. Each of these configurations provides examples of implementations configured to optimize resonator performance, anchor quality factor, and mechanical stability.

FIG. 12 illustrates a top-down view of a piezoelectric MEMS resonator device 1200 according to one or more embodiments, showing the planar layout of a thin-film piezoelectric layer 1204 relative to an underlying resonant body 1206. The resonant body 1206, in at least some embodiments, is formed from a bulk portion of an underlying substrate comprised of, for example, a low-acoustic-loss material, such as silicon, silicon carbide, diamond, sapphire, or other suitable material. Thin-film piezoelectric layer 1204, which overlays resonant body 1206, is configured to electrically excite and sense mechanical vibrations within resonant body 1206. The piezoelectric layer 1204 is formed from materials AlN, LiNbO₃, LiTaO₃, PZT, PMN-PT, doped/alloyed variants thereof, a combination thereof, or the like, as previously described. Selectively etched or otherwise formed openings 1226 (also referred to herein as vias “1226” or “regions or areas 1226”) in the piezoelectric layer 1204 are depicted by diagonally patterned areas, with these diagonal patterns representing the absence of piezoelectric material and the absence of the underlying resonant body 1206 within these regions. Thus, the etched openings 1226 correspond to vias or voids passing fully through the piezoelectric layer and positioned at locations where resonant body 1206 is not present, analogous to the openings 112 in FIG. 1 described above. Between these etched regions 1226 are intact portions 1228 (also referred to as “segments 1228” or “regions 1228”) of the piezoelectric layer 1204. These intact portions 1228, in at least some embodiments, function as electromechanical transducers by converting electrical signals into mechanical vibrations and sensing mechanical vibrations by converting them back into electrical signals. Furthermore, intact portions 1228 provide structural support and mechanical anchoring for the resonant body 1206 at minimal-displacement nodal points, effectively minimizing acoustic energy leakage and anchor loss, thereby substantially enhancing resonator performance and overall quality factor. Electrodes configured for signal transduction are not explicitly illustrated in FIG. 12 for clarity.

FIGS. 13 to 16 provide cross-sectional views taken along line A-A of FIG. 12, illustrating various structural embodiments with distinct layering arrangements configured to optimize specific acoustic, mechanical, and electrical properties. For example, in FIG. 13 the resonant body 1206 is formed from a portion of a bulk substrate, which is mechanically isolated from adjacent substrate regions 1314 by selectively fabricated etched gaps 1316. These gaps 1316 ensure robust mechanical isolation, significantly reducing unwanted acoustic energy leakage into the substrate and thereby minimizing anchor loss. The thin-film piezoelectric layer 1204 is disposed either directly or indirectly atop the resonant body 1206. These etched regions 1226 provide electrical and mechanical isolation, defining and optimizing active transduction regions and facilitating efficient electromechanical coupling. The intact regions 1228 of piezoelectric layer 1204, positioned between etched regions 1226, provide mechanical anchoring of the resonant body 1206 at minimal-displacement nodal points, ensuring optimal suspension and minimized acoustic coupling to the surrounding structure.

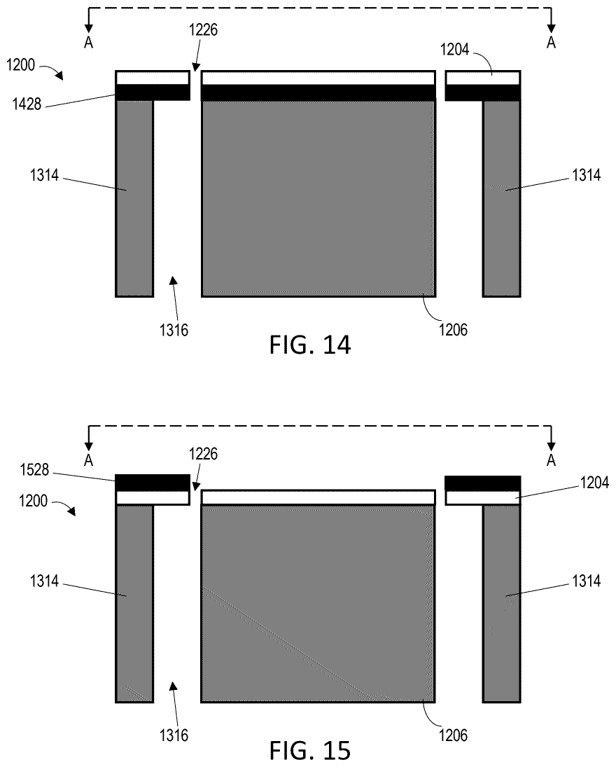

FIG. 14 illustrates a configuration in which at least one additional layer 1428, such as a structural and/or functional layer, is positioned directly or indirectly atop a top-most surface (with respect to the orientation of FIG. 14) of substrate regions 1314 and resonant body 1206. In the illustrated example, the thin-film piezoelectric layer 1204 is formed directly or indirectly on top of the additional layer 1428. Both the piezoelectric layer 1204 and the underlying additional layer 1428 include selectively etched regions 1226 that form aligned vias or openings extending fully through these layers. These openings expose the gaps 1316, which separate and mechanically isolate the resonant body 1206 from the surrounding substrate regions 1314, thus further contributing to reduced acoustic coupling and anchor loss. The additional layer 1428 provides one or more functions, including mechanical reinforcement, improved stress management, enhanced acoustic isolation, electrical insulation or conduction, additional electrode functionality, or improved electromechanical transduction. Examples of materials suitable for the additional layer 1428 include, for example, dielectric or structural films, such as silicon oxide (SiO₂), silicon nitride (Si₃N₄), polysilicon, metal layers, or combinations thereof. Selective etching of both the piezoelectric layer 1204 and the underlying additional layer 1428 ensures that portions 1228 of the piezoelectric layer 1204 remain between etched areas 1226, enabling precise definition of electrodes (not shown for clarity) and optimized electromechanical coupling.

Additionally, the selective patterning and alignment of the etched areas 1226 in both layers 1204 and 1428 define isolation gaps and expose underlying structural boundaries, thereby strategically positioning intact portions of these layers at minimal displacement nodal regions. These intact portions function as anchor points for mechanically suspending the resonant body 1206, significantly reducing acoustic energy leakage and anchor loss, and consequently enhancing resonator performance and anchor quality factor. Moreover, the additional layer 1428 may be selectively patterned to introduce engineered acoustic bandgap characteristics or tailored stress distribution, further optimizing the acoustic and mechanical properties of the resonant structure for specific applications, thereby improving overall reliability and performance of the piezoelectric MEMS resonator.

FIG. 15 illustrates another configuration in which an additional layer 1528, such as a structural and/or functional layer, is positioned directly (or indirectly) atop the thin-film piezoelectric layer 1204. In this embodiment, the additional layer 1528 is selectively patterned so that it is disposed primarily over the substrate regions 1314, forming peripheral portions aligned generally above these substrate regions while leaving the central region above the resonant body 1206 substantially open. In this manner, the peripheral positioning of the additional layer 1528 provides targeted mechanical reinforcement, optimized stress distribution, and enhanced acoustic isolation specifically at the substrate anchoring regions, rather than centrally over the resonator's active area as depicted in FIG. 14. This selective configuration effectively strengthens mechanical robustness at the anchor points, minimizes anchor loss, and reduces acoustic energy leakage into the substrate, collectively contributing to enhanced resonator stability and improved overall quality factor (Q).

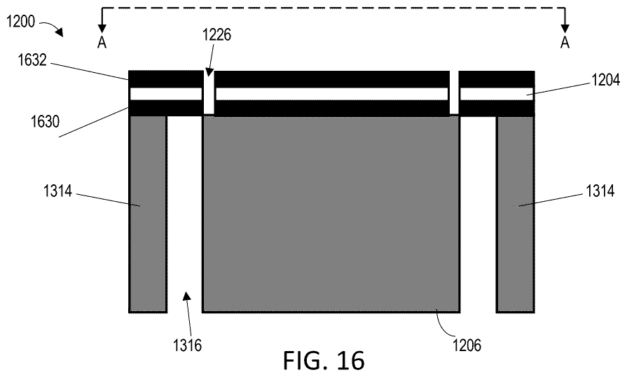

FIG. 16 illustrates yet another configuration incorporating multiple additional layers, such as multiple structural layers, multiple functional layers, or a combination thereof. For example, a first additional layer 1630 is positioned directly atop the substrate regions 1314 and resonant body 1206. The thin-film piezoelectric layer 1204 is disposed directly (or indirectly) atop this first additional layer 1630. A second additional layer 1632 is positioned atop piezoelectric layer 1204.

Both the first and second additional layers 1630, 1632 comprise the same or different materials, such as structural, dielectric, or conductive materials such. In at least some embodiments, these layers 1630, 1632 are selectively etched to form openings or vias 1226 that align vertically through the multilayer structure, including through the piezoelectric layer 1204, thereby defining gaps 1316 that mechanically isolate and suspend the resonant body 1206 from adjacent substrate regions 1314. This stacked multilayer configuration provides maximum mechanical robustness, significantly improved acoustic isolation, optimized stress management, and enhanced electromechanical coupling efficiency. Moreover, in at least some embodiments, the selectively one or more of the additional layers 1630, 1632 can be configured to function as phononic crystals, introducing controlled acoustic bandgap effects. These phononic crystal structures further minimize acoustic energy leakage and anchor loss, substantially enhancing resonator quality factor (Q) and overall device reliability and stability.

Collectively, the embodiments illustrated in FIGS. 12 to 16 underscore the versatility and broad configurability of the disclosed thin-film piezoelectric MEMS resonator structures, demonstrating various layer combinations and structural arrangements. These configurations enable optimized mechanical, acoustic, electrical, and thermal properties, facilitating highly customizable MEMS resonators tailored specifically for advanced timing applications, ultra-stable frequency references, precision frequency generation circuits, and demanding sensor systems requiring minimal phase noise, exceptional frequency stability, and robust integration capabilities.

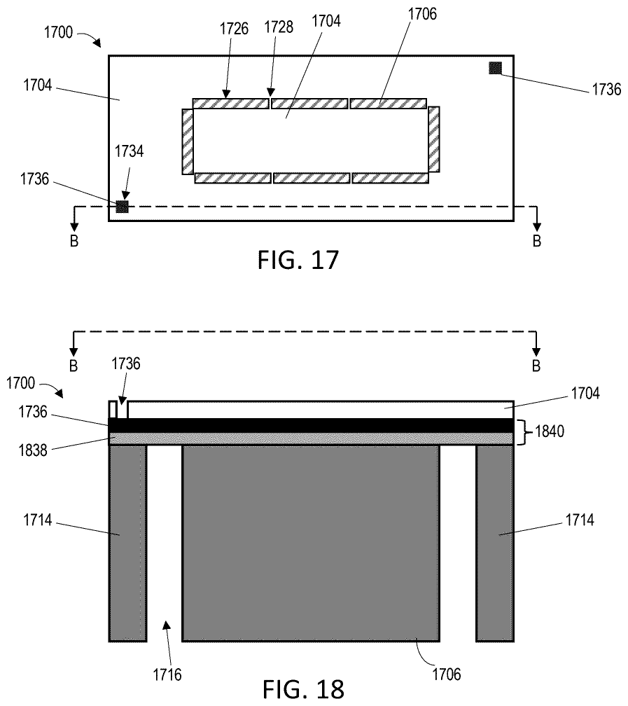

FIGS. 17 and 18 illustrate another embodiment of a thin-film piezoelectric MEMS resonator 1700, configured for applications that require temperature stability and precise thermal management, such as oven-controlled oscillators. FIG. 17 provides a top-down view of resonator 1700, while FIG. 18 illustrates a corresponding cross-sectional view taken along line B-B of FIG. 17. As illustrated in FIG. 17, resonator 1700 includes a resonant body 1706, which, similar to earlier embodiments, is formed from an underlying low-loss substrate material such as silicon, silicon carbide, diamond, sapphire, or the like. The resonant body 1706 is mechanically supported and suspended by the thin-film piezoelectric layer 1704, which functions both as an electromechanical transducer, which excites and senses mechanical vibrations, and as a structural suspension and anchor. Etched openings or vias 1726 are formed in the piezoelectric layer 1704, defining gaps that mechanically isolate the resonant body 1706 from adjacent substrate regions 1714. The intact regions 1728 of the piezoelectric layer 1704 between these etched openings 1726 mechanically anchor and suspend the resonant body 1706 at minimal displacement nodal points, thereby significantly minimizing anchor loss and acoustic leakage into the surrounding substrate. Electrodes configured to electrically excite and sense mechanical vibrations are not explicitly illustrated in FIG. 17 for brevity.

Additionally, FIG. 17 illustrates an etched via 1734 formed through the piezoelectric layer 1704, exposing a first layer 1736 of an underlying silicon-on-insulator (SOI) layer 1840 (FIG. 18). This SOI layer 1840 functions as a heater, enabling current flow (e.g., an Iₕₑₐₜₑᵣ) through the resonant body structure. By passing electrical current through the SOI heater layer 1840, the resonant body can be actively heated, maintaining a stable, elevated operating temperature. This configuration is particularly beneficial for applications such as oven-controlled MEMS oscillators (OCMO), where precise thermal control significantly improves frequency stability and reduces frequency drift arising from environmental temperature fluctuations.

FIG. 18 illustrates the resonant body 1706 formed within substrate regions 1714 and separated by etched regions or gaps 1716, providing mechanical isolation from adjacent substrate regions 1714. The SOI layer 1840 is positioned directly (or indirectly) atop the resonant body 1706 and the substrate regions 1714. In at least some embodiments, the SOI layer 1840 comprises a first layer 1736 (also referred to herein as “SOI heater layer 1736”), such as a silicon device layer, positioned directly (or indirectly) atop a second layer 1838, such as a silicon dioxide (SiO₂) insulating layer. The insulating layer 1838 electrically isolates the SOI heater layer 1736 from the underlying substrate regions, allowing the SOI heater layer 1736 to effectively function as a heating element by enabling controlled passage of electrical current to generate localized heating. In at least some embodiments, the SOI heater layer 1736 is configured to be electrically connected to a controlled voltage or current source, enabling precise and regulated heating to stabilize the resonator's operating temperature and enhance frequency stability. The thin-film piezoelectric layer 1704 is disposed directly (or indirectly) atop the SOI heater layer 1736. The vias 1734 formed within the piezoelectric layer 1704 expose a region of the SOI heater layer 1736, facilitating direct electrical contact. In operation, current introduced through the SOI heater layer 1736 elevates the resonant body's temperature to a stable operating point, thereby realizing a self-ovenized MEMS resonator structure.

Collectively, the embodiment depicted in FIGS. 17 and 18 illustrates an advanced structural configuration for MEMS resonators that actively manage device temperature using integrated SOI-based heater elements. By leveraging this heating capability, resonator frequency stability and precision are substantially improved, particularly suited to oscillator applications requiring minimal temperature-induced frequency drift, high long-term stability, and low phase noise characteristics. This self-ovenized approach aligns well with advanced oscillator requirements such as those in navigation, telecommunications, and precision instrumentation systems.

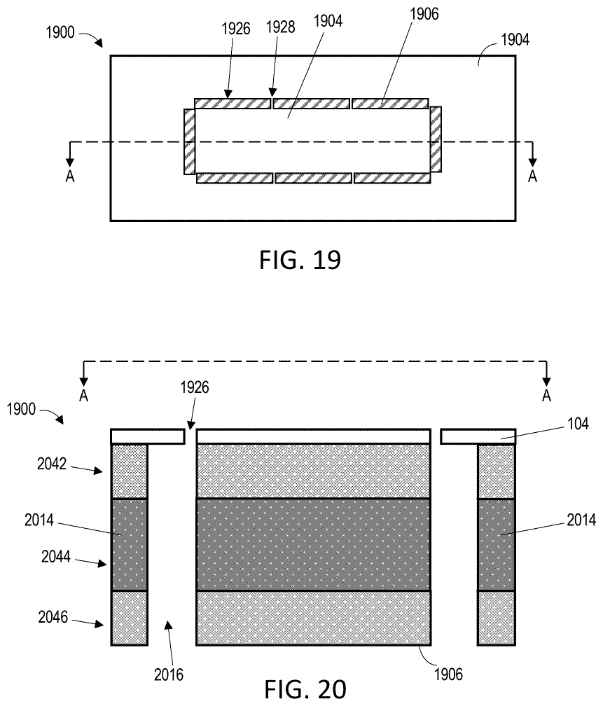

Referring now to FIGS. 19 and 20, these figures illustrate an additional embodiment of a piezoelectric MEMS resonator 1900 incorporating substrates engineered with different doping profiles to achieve passive temperature compensation, thereby significantly improving frequency stability over temperature variations. FIG. 19 provides a top-down view similar to FIG. 12, illustrating resonator structure 1900 including a thin-film piezoelectric layer 1904 configured with etched openings or vias 1926. These etched openings 1926 form gaps or voids in the piezoelectric layer 1904, isolating the resonant body 1906, which is formed from portions of the underlying substrate 2014 (FIG. 20), from adjacent substrate regions. Intact regions 1928 of piezoelectric layer 1904 remain between these openings 1926, mechanically suspending and anchoring the resonant body 1906 at minimal displacement nodal points, thereby significantly reducing anchor loss and acoustic energy leakage as described previously.

FIG. 20 provides a corresponding cross-sectional view taken along line A-A of FIG. 19, depicting the structural arrangement of the resonant body 1906. In this embodiment, the substrate regions 2014, including the resonant body 1906 formed therein, comprises distinct regions or portions 2042, 2044, and 2046. Each of these substrate portions can have distinct doping profiles, doping concentrations, and/or different types of dopants. Suitable dopants may include n-type dopants such as phosphorus, arsenic, or antimony, or p-type dopants such as boron, and these dopants may be incorporated at varying concentrations within the respective substrate portions. Such doping variations within substrate portions 2042, 2044, and 2046 intentionally create a substrate and resonant body structure characterized by regions having opposing temperature coefficients of elasticity.

For example, these intentionally varied doping profiles and concentrations within substrate portions 2042, 2044, and 2046 collectively interact to produce an aggregate mechanical response exhibiting a significantly reduced or near-zero temperature coefficient of elasticity (TCE). This effectively minimizes temperature-induced frequency drift, yielding resonators with substantially improved frequency stability over temperature, i.e., a greatly reduced or near-zero temperature coefficient of frequency (TCF). The outcome is a passively temperature-compensated resonator, capable of maintaining frequency stability without active temperature control such as heaters or thermoelectric elements.

By employing substrates and resonant bodies structured with different doping profiles and concentrations as illustrated in FIGS. 19 and 20, the disclosed piezoelectric MEMS resonators achieve considerable performance advantages. This doping-based passive compensation approach is especially beneficial for applications demanding high precision frequency stability, including frequency references, precision timing devices, telecommunications, navigation systems, and sensor applications. The passive temperature compensation described here further complements the previously disclosed anchoring configurations and structural arrangements, thereby enhancing the versatility and applicability of the disclosed MEMS resonator technology.

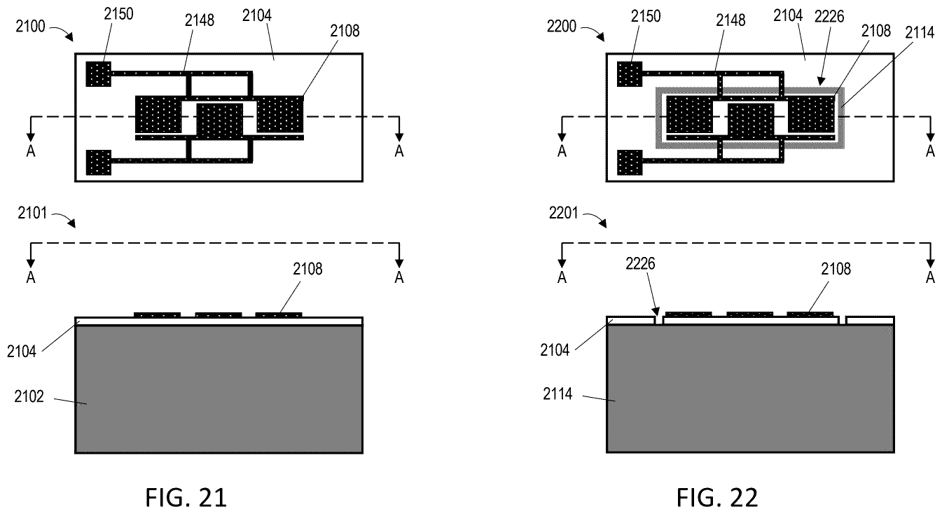

FIGS. 21 to 23 illustrate an example of a fabrication process flow for the thin-film piezoelectric MEMS resonators of one or more embodiments. Referring first to FIG. 21, which illustrates both a top view 2100 and a corresponding cross-sectional view 2101, an initial fabrication stage is illustrated. In this stage, a substrate layer 2102 is prepared as the foundational layer upon which the resonator structure is constructed. The substrate 2102, in at least some embodiments, comprises a low-loss acoustic material (e.g., silicon, silicon carbide, diamond, sapphire, or a combination thereof) that provides optimal acoustic, thermal, and mechanical properties suitable for MEMS resonators. Directly atop substrate 2102, a thin-film piezoelectric layer 2104 is deposited using thin-film deposition techniques, such as sputtering, chemical vapor deposition (CVD), atomic layer deposition (ALD), or epitaxial growth. Alternatively, the thin-film piezoelectric layer 2104 may be formed by bonding a separately prepared piezoelectric film onto the substrate or electrode layer using wafer bonding techniques, adhesive bonding, eutectic bonding, or other suitable bonding methods.

As described above, the thin-film piezoelectric layer 2104 comprises piezoelectric materials, such as AlN, LiNbO₃, LiTaO₃, PZT, PMN-PT, or doped/alloyed variants thereof. On top of the piezoelectric layer 2104, top metal electrodes 2108 are deposited and patterned. The metal electrodes 2108 are formed by microfabrication processes, such as metal evaporation, sputtering, or plating, followed by selective photolithography and etching steps to define electrode geometries. In FIG. 21, the metal electrodes 2108 are interconnected by conductive traces 2148 to external bonding pads 2150 or terminals, enabling electrical excitation and sensing of mechanical vibrations within the resonator structure. These patterned electrodes 2108 and interconnecting metal traces 2148 define the electromechanical transducer functionality required for the resonator device.

FIG. 22, which illustrates both a top view 2200 and a corresponding cross-sectional view 2201, depicts the next step in the fabrication sequence. Here, selective etching or removal of portions of piezoelectric layer 2104 is conducted to form openings or vias 2226. These etched areas 2226 expose upper surfaces of the underlying substrate 2012. The etching, in at least some embodiments, is achieved using, for example, wet chemical etching, reactive ion etching (RIE), or inductively coupled plasma (ICP) etching. The openings 2226 expose portions of the underlying substrate 2102 that will be selectively removed in subsequent steps to structurally isolate and define the resonant body. These openings 2226 thereby facilitate the formation of gaps or isolation regions surrounding the resonant body. After this etching step, intact regions of the piezoelectric layer 2104 remain between the openings 2226, forming thin-film anchor structures for mechanically suspending the subsequently formed resonant body at minimal displacement nodal points, as discussed earlier.

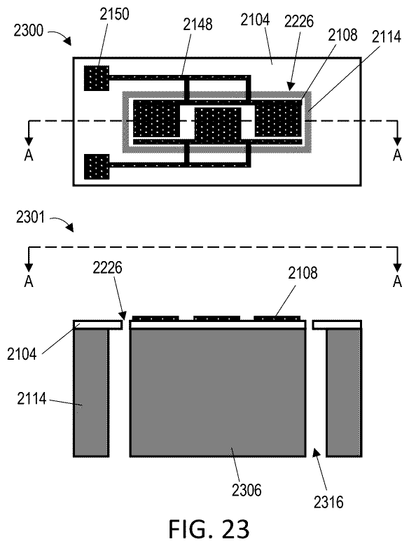

FIG. 23, which illustrates both a top view 2300 and a corresponding cross-sectional view 2301, illustrates the subsequent fabrication step involving backside etching of substrate 2102. In this step, the backside of substrate 2012 is selectively etched using, for example, deep reactive ion etching (DRIE) or wet chemical etching techniques. This backside etching forms cavity or void regions 2316, and in doing so, defines and releases the resonant body 2306 from substrate regions 2114. As a result, the resonant body 2306 is mechanically isolated from surrounding substrate regions 2114 and structurally suspended solely by the intact portions of thin-film piezoelectric layer 2104, with electrode layer 2108 positioned above. The release of the resonant body 2306 and the formation of cavities or void regions 2316 ensures mechanical and acoustic isolation, significantly reducing anchor loss and enhancing resonator quality factor and overall stability.

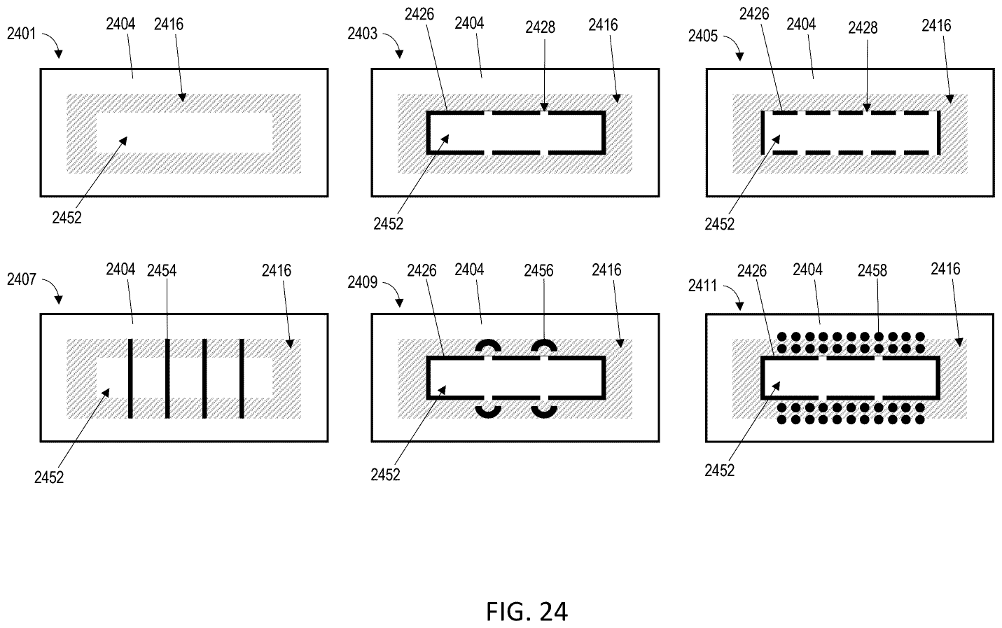

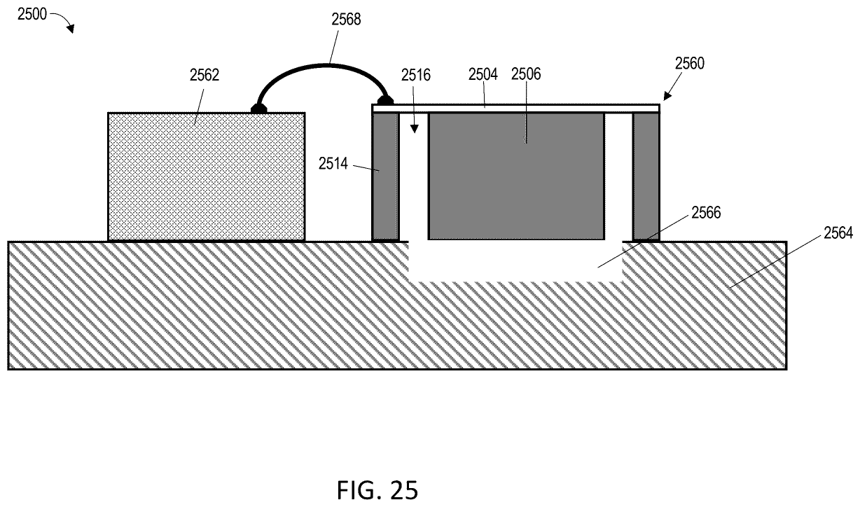

FIG. 24 illustrates top views of different example configurations of thin-film piezoelectric MEMS resonators disclosed herein, each demonstrating different structural arrangements and patterning schemes of the thin-film piezoelectric layer 2404 to optimize resonator performance, minimize anchor loss, and tailor acoustic and mechanical characteristics. In each illustration, the diagonally patterned regions 2416 represent the underlying gap region discussed above, shown here as if visible through the piezoelectric layer 2404 solely for clarity and ease of understanding.

Configuration 2401 depicts a structure in which a continuous thin-film piezoelectric layer 2404 is present around a central resonant region 2452. Beneath the piezoelectric layer 2404, although not explicitly visible in this configuration, is the resonant body. Surrounding this resonant body is an underlying gap region 2416 (illustrated as the diagonally patterned region, shown here as if transparent for clarity and illustration purposes only), representing the absence of material beneath the piezoelectric layer 2404 in this peripheral area. The continuous, intact piezoelectric layer 2404 thus mechanically anchors and suspends the resonant body exclusively at its topmost layer, effectively reducing anchor loss and enhancing mechanical isolation and resonator quality factor.

Configuration 2403 illustrates an arrangement of the piezoelectric layer 2404, in which selective etched openings 2426 (represented by solid black areas) are formed in the piezoelectric layer 2404. The intact portions 2428 of the piezoelectric layer 2404 between these openings 2426 provide segmented anchoring structures that position mechanical supports at minimal-displacement nodal points, further minimizing anchor loss and optimizing mechanical isolation. Although not explicitly illustrated, the resonant body is disposed generally beneath the piezoelectric layer 2404, and is anchored and suspended by these segmented piezoelectric regions. This selective patterning of the piezoelectric layer 2404 enhances electromechanical transduction efficiency and improves resonator quality factor by limiting mechanical coupling exclusively to carefully chosen anchoring points.

Configuration 2405 depicts a further segmented arrangement of the piezoelectric layer 2404. Selective etched openings 2426 (represented by solid black areas) formed within the piezoelectric layer 2404 define distinct, separated piezoelectric segments or regions 2428. The resonant body is mechanically anchored and suspended by these segmented piezoelectric regions 2428. The selective segmentation of the piezoelectric layer 2404 into discrete regions 2428 allows tailored mechanical anchoring exclusively at minimal-displacement nodal points, further minimizing acoustic energy leakage, enhancing electromechanical coupling efficiency, and significantly improving resonator quality factor and mechanical isolation.

Configuration 2407 introduces additional etched openings 2454 formed within the central active region 2452 of the piezoelectric layer 2404. In contrast to the axial arrangement of peripheral openings 2426 shown in configurations 2403 and 2405 (extending along both the longer and shorter dimensions of the resonator), the openings 2454 in configuration 2407 extend laterally, traversing the shorter dimension of the resonator. These laterally positioned openings 2454 segment the piezoelectric layer 2404 into multiple discrete piezoelectric strips or segments 2428 arranged across the width of the resonant body. This lateral segmentation enables targeted excitation and sensing of specific lateral mechanical vibration modes, provides precise frequency tuning, and facilitates improved stress management. Thus, the selective lateral segmentation provided by the openings 2454 enhances electromechanical transduction efficiency, further minimizes anchor loss, and offers finer control over mechanical resonance characteristics and resonator performance.

Configuration 2409 integrates arcuate-shaped acoustic reflector structures 2456 within the piezoelectric layer 2404, arranged around selective etched openings 2426 and adjacent to the segmented anchoring structures provided by the intact portions 2428 of the piezoelectric layer 2404 between the openings 2426. The acoustic reflectors 2456 serve as in-plane acoustic barriers, reflecting acoustic waves and mechanical vibrations back into the resonant body. This targeted acoustic reflection effectively minimizes acoustic energy leakage, significantly reducing anchor loss, and thereby greatly enhancing resonator stability, quality factor, and overall acoustic isolation.

Configuration 2411 illustrates the incorporation of phononic crystal structures 2458, represented by a periodic array of circular etched openings or voids formed within the thin-film piezoelectric layer 2404. These phononic crystals 2458 are positioned around the central active region 2452, adjacent to the periphery of the resonant body (not explicitly shown here). These phononic crystals 2458 introduce engineered acoustic bandgap effects, effectively attenuating or reflecting acoustic waves at specific frequency ranges. Consequently, this arrangement drastically minimizes acoustic energy leakage and anchor loss, providing exceptional mechanical isolation. Resonators employing these phononic crystal configurations demonstrate significantly enhanced resonator quality factor, superior frequency stability, and minimal phase noise, highly beneficial for high-performance timing and frequency reference applications.

FIG. 25 illustrates a side cross-sectional view of an example oscillator system 2500 incorporating a thin-film piezoelectric MEMS resonator according to one or more embodiments. In this example, FIG. 25 shows an arrangement in which a MEMS resonator die 2560, comprising substrate regions 2514 and a resonant body 2506, is integrated with an electronics die 2562 on a substrate or interposer 2564. The resonant body 2506 is structurally suspended and anchored by a thin-film piezoelectric layer 2504 at minimal-displacement nodal regions, consistent with previously described embodiments. Surrounding the resonant body 2506 are gap regions or cavities 2516, representing areas where substrate material has been removed to mechanically isolate the resonant body 2506, thus significantly reducing anchor loss and acoustic leakage. This structural arrangement ensures optimized mechanical isolation and enhances the resonator's quality factor and overall stability.

The substrate or interposer 2564 provides a mechanical and electrical interface for integrating the MEMS resonator die 2560 and electronics die 2562 into a compact, unified oscillator assembly. The interposer 2564, in at least some embodiments, comprises, for example, ceramic substrates, silicon-based substrates, laminate substrates, organic substrates, printed circuit boards (PCBs), or similar interconnection platforms employed in microelectronics and MEMS integration. A cavity 2566 formed within the interposer 2564 is positioned directly underneath the resonant body 2506 to prevent mechanical and acoustic coupling between the MEMS resonator die 2560 and interposer 2564, thereby further minimizing acoustic leakage, anchor loss, and external mechanical perturbations, which collectively enhance frequency stability and oscillator performance.

In at least some embodiments, the electronics die 2562 comprises oscillator circuitry electrically coupled to the electrode pattern (not shown in FIG. 25) formed on the thin-film piezoelectric layer 2504. This oscillator circuitry is configured to drive and detect the mechanical vibrations of the MEMS resonator die 2560, generating a stable clock signal based on the mechanical vibrations of the resonating structure. The electronics die 2562 is positioned adjacent to the MEMS resonator die 2560, and electrically connected thereto through suitable interconnections, such as wire-bond interconnections 2568. These interconnections 2568 enable the transfer of electrical excitation signals to the piezoelectric layer to generate mechanical vibrations in the resonant body 2506, as well as the sensing of mechanical vibrations by converting them back into electrical signals, wherein the electrical signals are used to generate or stabilize the oscillator clock output. Although FIG. 25 illustrates the MEMS resonator die 2560 positioned adjacent to the electronics die 2562 on the interposer 2564, alternative embodiments can include different integration strategies. For example, in other configurations, the MEMS resonator die 2560 can be vertically stacked directly atop the electronics die 2562, or fabricated monolithically on the same die as the electronics, providing further miniaturization, integration, and improved electrical performance.

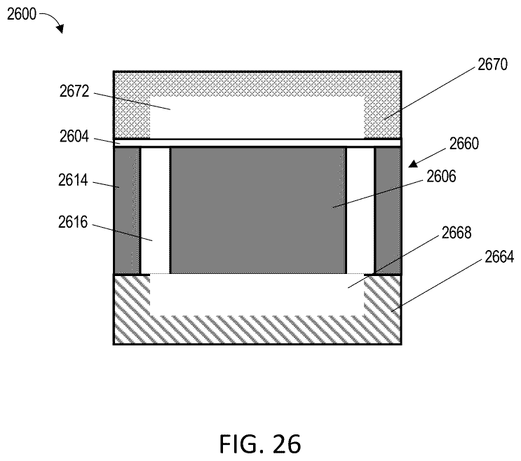

FIG. 26 illustrates a cross-sectional side view of an example packaging solution 2600 for the one or more of the thin-film piezoelectric MEMS resonators described herein. In this example, a resonator die 2660 comprises a resonant body 2606 that is mechanically anchored and suspended by a thin-film piezoelectric layer 2604. Surrounding the resonant body 2606 are etched gaps or cavities 2616, which provide mechanical isolation from adjacent substrate regions 2614 and minimize anchor loss, consistent with previously described configurations. The resonator die 2660 is mounted onto a base substrate or interposer 2664, similar to the interposed 2566 described above with respect to FIG. 25. Within the interposer 2664, a cavity 2668 is formed and positioned directly underneath resonant body 2606 to eliminate acoustic coupling and reduce mechanical interference, thus further enhancing the resonator's frequency stability and minimizing external mechanical disturbances.

FIG. 26 further illustrates an upper capping die 2670 (also referred to herein as “capping structure 2670”) disposed above the resonator die 2660. This upper capping die 2670 is provided with an internal cavity 2672, configured to define an enclosed sealed environment surrounding the resonant body 2606. In at least some embodiments, the cavity 2672 is evacuated to create an evacuated space (e.g., a vacuum or substantially vacuum environment), or alternatively filled with a controlled inert gas, to minimize environmental effects, reduce air damping, and enhance resonator stability, quality factor, and frequency consistency. In at least some embodiments, the upper capping die 2670 comprises glass, silicon, silicon carbide, ceramic, or other suitable dielectric or semiconductor materials. Additionally, the upper capping die 2670 may be hermetically sealed to the underlying resonator die using methods such as wafer-level bonding techniques (e.g., anodic bonding, glass frit bonding, eutectic bonding, or metal bonding). Such sealing techniques provide reliable and long-term environmental isolation, protecting the resonator structure from humidity, contamination, and other environmental factors that might degrade performance.

Alternatively, in other embodiments, instead of a discrete upper capping die 2670, sealing can be achieved through the deposition of a sacrificial layer followed by a capping layer deposition. In these embodiments, a sacrificial material (e.g., silicon oxide, polymer, or other selectively removable materials) is deposited onto the resonator die 2660, followed by deposition of a permanent capping material (e.g., silicon nitride, polysilicon, metal, ceramic, or glass layers). The sacrificial layer is subsequently selectively removed (etched away), leaving behind a sealed cavity surrounding resonant body 2606, thereby forming a self-packaged, sealed resonator structure. This approach allows wafer-level packaging, enabling mass fabrication and high yield, beneficial for cost-effective MEMS resonator manufacturing.

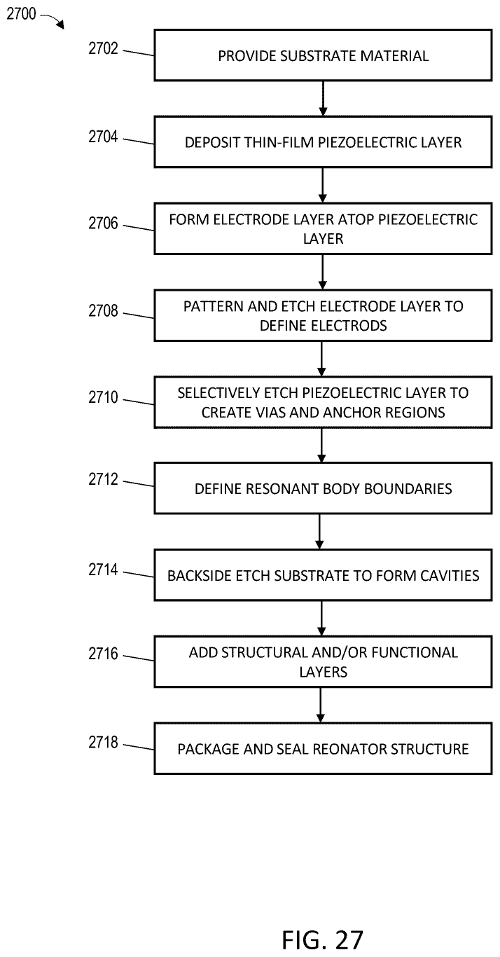

FIG. 27 illustrates a flow diagram of a method 2700 for fabricating a thin-film piezoelectric MEMS resonator structure, according to one or more embodiments disclosed herein. The processes described with respect to method 2700 are detailed further above with reference to, for example, FIGS. 21 to 23. The method 2700 is not strictly limited to the sequence of operations shown in FIG. 27, as some operations can occur concurrently, in parallel, or in different orders. Additionally, the method 2700 may include one or more operations beyond those depicted in FIG. 27. At block 2702, a substrate material 2102 is provided. The substrate 2102 serves as the foundational layer from which the resonant body 2306 is subsequently defined. At block 2704, a thin-film piezoelectric layer 2104 is deposited onto the substrate 2102. The piezoelectric layer is formed by techniques such as sputtering, CVD, ALD, or other suitable thin-film deposition methods.

At block 2706, an electrode layer 2108 is formed atop the thin-film piezoelectric layer 2104. The electrode layer 2108 comprises, for example, conductive materials such as aluminum, gold, platinum, copper, titanium, or multilayer metal stacks deposited via physical vapor deposition PVD, sputtering, evaporation, or electrodeposition, and subsequently patterned using photolithography and selective etching techniques. At block 2708, the electrode layer 2108 is selectively patterned and etched to define specific electrode geometries optimized for exciting and sensing mechanical vibrations within the underlying resonant body 2306. At block 2710, portions of the thin-film piezoelectric layer 104 are selectively etched to create vias or openings 2226. These etched openings 2326 define piezoelectric anchor regions for mechanical support at minimal displacement nodal points and provide electrical isolation between electrode structures 2108.

At block 2712, the boundaries of the resonant body 2306 are defined from the topside by selectively etching or patterning portions of the underlying substrate 2102 through the previously created vias or openings 2226 in the piezoelectric layer 2104. This step determines the lateral extent and geometry of the resonant body 2306. At block 2714, backside etching of the substrate 2102 is performed using, for example, deep reactive ion etching (DRIE), wet chemical etching, or other suitable etching processes. This backside etching step creates cavity or void regions 2316 beneath the resonant body 2306, fully defining and mechanically isolating the resonant body structure, ensuring its suspension solely by the thin-film piezoelectric anchor regions.

At block 2716, additional structural or functional layers, such as acoustic reflectors, phononic crystals, stress-management films, or hermetic capping layers, may be deposited or patterned on or around the resonant structure to further optimize acoustic isolation, mechanical robustness, and resonator stability. At block 2718, packaging and sealing of the MEMS resonator structure are performed. The resonator die may be bonded or hermetically sealed to an upper capping die, integrated with an interposer substrate, or encapsulated via sacrificial and permanent capping layers to provide a stable, controlled environment that protects the resonator from external mechanical and environmental factors.

As such, the piezoelectric resonator of one or more embodiments offers several advantages over existing piezoelectric microelectromechanical systems (MEMS) resonators. By using a temperature-stable and high-quality factor (low noise) platform, the device achieves a very low loss (approaching the material limited loss) and reliable resonance signal to be used for stable clock generation. This is enabled by the thin-film suspended anchor that can be tailored for connecting to a resonant body only through its zero displacement nodes, which for the case of TLM that offers low TED occurs at the top corners of the resonant body. This configuration eliminates anchor loss and provides a path for reaching the material limit of loss since TED and anchor loss are mitigated. This innovative approach enables the use of thin-film piezoelectric materials as anchors, which can be precisely controlled to minimize losses. Additionally, the substrates used in fabrication are cost-effective and CMOS compatible (e.g., a few 100 μm thick silicon with a few μm thick aluminum nitride and few 100 nanometer (nm) electrodes on top/bottom), allowing for batch production of, for example, thousands of devices at a minimal cost per unit (e.g., a few cents). Furthermore, the piezoelectric resonator of one or more embodiments not only addresses the limitations of existing piezoelectric MEMS resonators by mitigating the dominant loss sources, including thermoelastic damping (TED) and anchor loss, but it also provides high temperature stability of resonance frequency by enabling integration of passive and active temperature compensation methods. This leads to a highly frequency-stable temperature point that can be used for implementing oven-controlled oscillators (MEMS equivalent to TCXOs) for ultra-stable clock generation in applications, such as navigation and military equipment. In contrast to commercially available MEMS oscillators, the piezoelectric resonator of one or more embodiments does not suffer from lower electromechanical coupling or higher noise due to anchoring losses. This makes the piezoelectric resonator suitable for use in low-power scenarios, such as Internet of Things (IoT) devices, where existing solutions are limited by their power consumption.

Although specific embodiments of the disclosure have been discussed herein, those having ordinary skill in the art will readily recognize that changes can be made to these specific embodiments without departing from the scope of the invention. The described examples and embodiments serve as illustrations and should not be interpreted as limiting the scope of the present disclosure. The appended claims, therefore, are intended to cover any and all such variations, modifications, and embodiments falling within the scope of the invention.

It is understood that some features disclosed herein may be utilized independently of others, and that particular features of the disclosed embodiments can be implemented in alternative embodiments without necessarily incorporating all of the features described herein. Thus, the descriptions provided herein illustrate exemplary implementations of the principles, teachings, and configurations of the present disclosure, and should not be interpreted as exclusive or exhaustive limitations thereof.

The structures, configurations, architectures, substrate materials, layers, and fabrication processes described herein serve as examples. Alternate architectures, structures, substrate materials, piezoelectric materials, electrode compositions, and fabrication steps may be employed while remaining within the scope of the present invention. For instance, the resonant body can be formed from other suitable low-loss substrate materials beyond silicon, silicon carbide, diamond, or sapphire. Similarly, alternative piezoelectric materials or composites thereof may be selected to optimize performance characteristics according to particular application requirements.

It will also be appreciated that terminology such as “on”, “over”, or “above”, as used in describing element relationships, indicates either direct contact or an arrangement in which intervening layers or components exist. In contrast, the terms “directly on”, “directly above”, and the like denote immediate contact without intermediate layers. Likewise, the terms “connected” and “coupled” encompass both direct and indirect connection or coupling, whereas “directly connected” or “directly coupled” specifically refer to immediate, uninterrupted relationships between elements.

Throughout the description, references to “one embodiment”, “an embodiment”, or similar phrases indicate that the particular feature, structure, or characteristic described in connection with that embodiment is included in at least one embodiment of the present principles. Such references appearing in different locations throughout the disclosure do not necessarily refer to the same embodiment.

Further, it is understood that elements referenced as “first”, “second”, etc., are identified solely to distinguish between multiple elements of similar character, and such labels do not imply any inherent order or hierarchy. Thus, a first element could alternatively be termed a second element, and vice versa, without deviating from the scope of the present invention.

Moreover, while example implementations have been illustrated and described herein, numerous modifications, substitutions, alterations, equivalents, and combinations thereof will be apparent to those skilled in the art. The present disclosure explicitly encompasses all such modifications and alterations as falling within the scope of the appended claims. Furthermore, various disclosed elements, features, layers, processes, or configurations may be combined or employed in isolation, except for mutually exclusive arrangements, to achieve desired functionality or performance.

The singular forms “a”, “an”, and “the” as used herein expressly encompass plural forms unless the context clearly indicates otherwise. Terms such as “comprises”, “comprising”, “includes”, and “including” specify the presence of stated features, steps, components, or elements but do not preclude the addition or presence of other features, steps, components, or elements.

Accordingly, the examples and embodiments described herein are presented by way of illustration rather than limitation. These descriptions are provided to facilitate understanding and appreciation of the invention, without intending to restrict or limit the broad scope of the appended claims.

1. A piezoelectric Micro-Electro-Mechanical Systems (MEMS) resonator comprising:
a substrate;
a thin-film piezoelectric layer disposed on the substrate;
an electrode pattern formed on the thin-film piezoelectric layer to induce mechanical vibrations in response to an electrical signal; and
a resonating structure configured to vibrate at a resonant frequency, wherein only a portion of the resonating structure interfacing with the thin-film piezoelectric layer is anchored to the substrate exclusively by the thin-film piezoelectric layer.

2. The resonator of claim 1, wherein the resonating structure is anchored by the thin-film piezoelectric layer exclusively at zero-displacement nodal points of the resonating structure.

3. The piezoelectric MEMS resonator of claim 2, wherein the zero-displacement nodal points correspond to peripheral corner regions of the resonating structure.

4. The piezoelectric MEMS resonator of claim 1, wherein the resonating structure comprises a higher-order thickness Lamé mode (TLM) in at least one of a thickness or lateral direction.

5. The piezoelectric MEMS resonator of claim 1, wherein the substrate comprises one of silicon, silicon carbide, diamond, or sapphire.

6. The piezoelectric MEMS resonator of claim 1, wherein the thin-film piezoelectric layer comprises at least one of aluminum nitride, lithium niobate, lithium tantalate, lead zirconate titanate, lead magnesium niobate-lead zirconate titanate, or doped or alloyed variants thereof.

7. The piezoelectric MEMS resonator of claim 1, wherein the substrate comprises different doping concentrations or dopant types configured to provide passive temperature compensation.

8. The piezoelectric MEMS resonator of claim 1, wherein the substrate comprises regions having opposing temperature coefficients of elasticity.

9. The piezoelectric MEMS resonator of claim 1, further comprising:
at least one of one or more structural layers or one or more functional layers disposed above or below the thin-film piezoelectric layer.

10. The piezoelectric MEMS resonator of claim 9, wherein the at least one of the one or more structural layers or the one or more functional layers is selectively patterned to form at least one reflector or at least one phononic crystal.

11. The piezoelectric MEMS resonator of claim 1, further comprising:
a silicon-on-insulator (SOI) layer disposed beneath the thin-film piezoelectric layer and configured to serve as a heating element for stabilizing resonance frequency by localized heating.

12. The piezoelectric MEMS resonator of claim 11, wherein the SOI layer is configured to be electrically connected to a controlled voltage or current source for heating.

13. The piezoelectric MEMS resonator of claim 1, wherein the resonating structure is mechanically isolated from surrounding substrate regions by etched gap regions formed in the substrate, and wherein the resonating structure is mechanically suspended solely by the thin-film piezoelectric layer.

14. An oscillator comprising:
a piezoelectric Micro-Electro-Mechanical Systems (MEMS) resonator comprising:
a substrate;
a thin-film piezoelectric layer disposed on the substrate;
an electrode pattern formed on the thin-film piezoelectric layer to induce mechanical vibrations in response to an electrical signal; and
a resonating structure configured to vibrate at a resonant frequency, wherein only a portion of the resonating structure interfacing with the thin-film piezoelectric layer is anchored to the substrate by the thin-film piezoelectric layer; and
oscillator circuitry electrically coupled to the electrode pattern and configured to drive the resonating structure at the resonant frequency and to generate a stable clock signal based on mechanical vibrations of the resonating structure.

15. The oscillator of claim 14, further comprising:
an interposer or base substrate supporting the resonating structure and the oscillator circuitry, wherein the interposer or base substrate includes a cavity positioned directly underneath the resonating structure to mechanically isolate the resonating structure.

16. The oscillator of claim 14, wherein the substrate comprises regions with differing doping concentrations or dopant types.

17. The oscillator of claim 14, further comprising:
a silicon-on-insulator (SOI) layer positioned between the thin-film piezoelectric layer and the substrate, the SOI layer including a silicon device layer disposed on an insulating silicon dioxide layer, wherein the silicon device layer is configured as a heating element to stabilize the resonant frequency of the resonating structure.

18. The oscillator of claim 14, further comprising:
a capping structure disposed above the resonating structure, the capping structure defining a sealed environment around the resonating structure, wherein the sealed environment comprises at least one of an evacuated space or an inert gas to minimize acoustic damping and improve frequency stability.

19. A method for fabricating a piezoelectric Micro-Electro-Mechanical Systems (MEMS) resonator, the method comprising:
providing a substrate;
depositing a first electrode layer on the substrate;
depositing or bonding a thin-film piezoelectric layer over the first electrode layer;
forming a second electrode layer over the thin-film piezoelectric layer;
patterning the first electrode layer, the thin-film piezoelectric layer, and the second electrode layer to define a resonant structure;
etching the substrate to release the resonant structure, thereby allowing the resonant structure to vibrate; and
anchoring only a portion of the resonating structure interfacing with the thin-film piezoelectric layer to the substrate using the thin-film piezoelectric layer.

20. The method of claim 19, further comprising:
forming a silicon-on-insulator (SOI) layer comprising a silicon device layer and an insulating silicon dioxide layer beneath the thin-film piezoelectric layer, wherein the silicon device layer is configured as a heating element.
